(19) United States
(12) Patent Application Publication
(10) Pub. No.: US 2026/0214951 A1
(43) Pub. Date: Jul. 23, 2026

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventor: Hideaki TAKENAKA, Himeji Hyogo (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 19/283,350

(22) Filed: Jul. 29, 2025

(30) Foreign Application Priority Data
Jan. 22, 2025 (JP) 2025-009292

(51) Int. Cl. H10D 62/10; H10D 8/60; H10D 62/832

(52) U.S. Cl. CPC H10D 62/107; H10D 8/60; H10D 62/8325

(57) ABSTRACT

A semiconductor device includes an element region, a termination region, a semiconductor layer including a first surface, and a second surface, a first electrode contacting the first surface, a second electrode contacting the second surface, a first resin member located on the first surface in the termination region, the first resin member covering an end part of the first electrode, and a second resin member covering the semiconductor layer, the first resin member, and the first electrode. The first resin member has an unevenness formed in a surface of the first resin member at a side opposite to the first surface.

### CROSS-REFERENCE TO RELATED APPLICATION

This application is based upon and claims the benefit of priority from Japanese Patent Application No.2025-009292, filed on Jan. 22, 2025; the entire contents of which are incorporated herein by reference.

### FIELD

Embodiments described herein relate generally to a semiconductor device.

### BACKGROUND

There is a vertical power control semiconductor device configured so that an end part of an upper surface electrode proximate to a termination region is protected with a resin.

### BRIEF DESCRIPTION OF THE DRAWINGS

FIG. 1 is a schematic plan view of a semiconductor device according to an embodiment;

FIG. 2 is an A-A cross-sectional view of FIG. 1; and

FIG. 3 is a B-B cross-sectional view of FIG. 1.

### DETAILED DESCRIPTION

According to one embodiment, a semiconductor device includes an element region; a termination region surrounding the element region; a semiconductor layer including a first surface, and a second surface positioned at a side opposite to the first surface; a first electrode contacting the first surface; a second electrode contacting the second surface; a first resin member located on the first surface in the termination region, the first resin member covering an end part of the first electrode; and a second resin member covering the semiconductor layer, the first resin member, and the first electrode, the first resin member having an unevenness formed in a surface of the first resin member at a side opposite to the first surface.

Exemplary embodiments will now be described with reference to the drawings. Similar components in the drawings are marked with like reference numerals. According to the embodiments below, a first conductivity type of semiconductor layers is described as an n-type, and a second conductivity type is described as a p-type; however, the first conductivity type may be the p-type; and the second conductivity type may be the n-type.

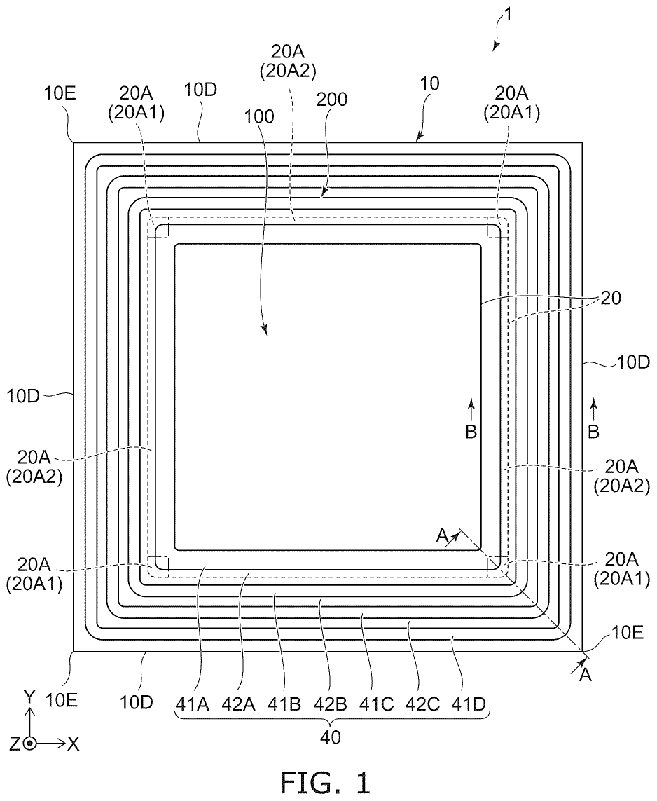

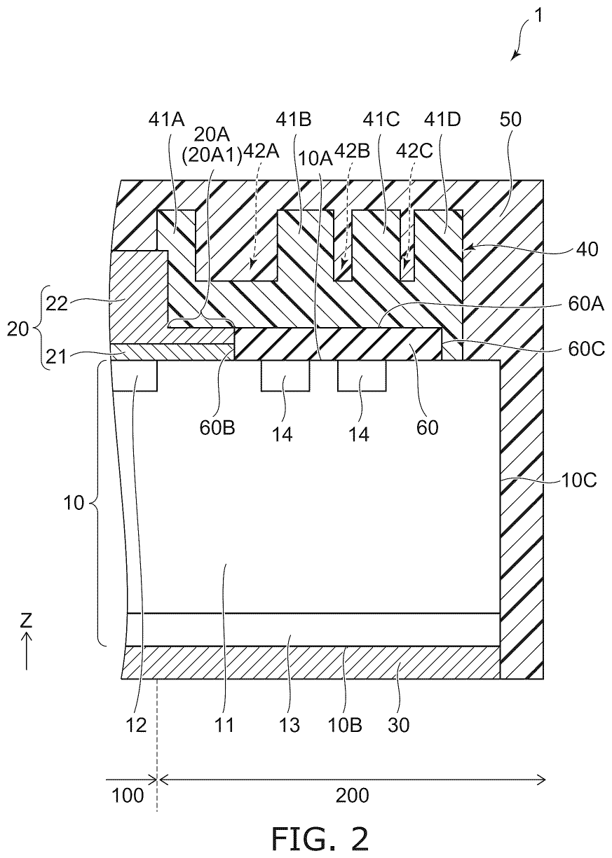

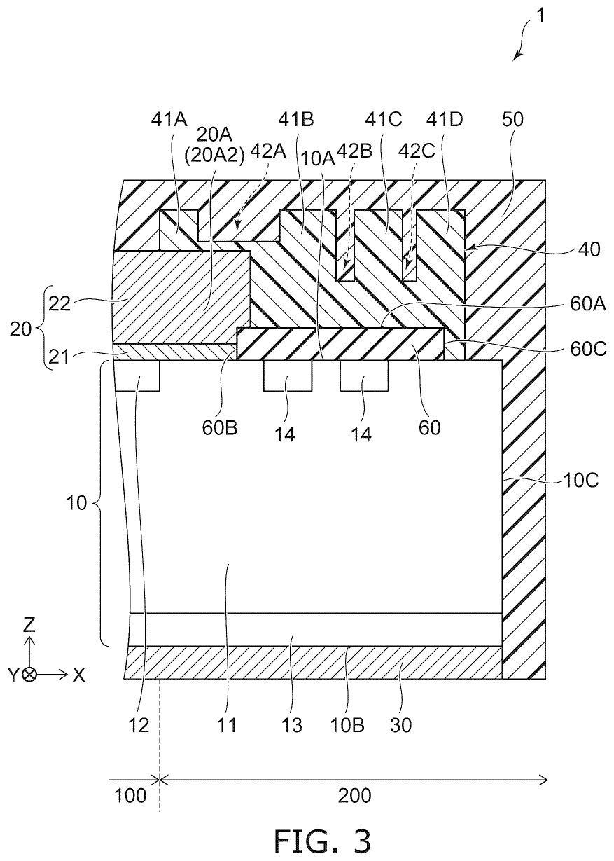

FIG. 1 is a schematic plan view of a semiconductor device 1 according to an embodiment. FIG. 2 is an A-A cross-sectional view of FIG. 1. FIG. 3 is a B-B cross-sectional view of FIG. 1. A second resin member 50 is not illustrated in FIG. 1.

In the drawings shown below, directions may be indicated using an X-axis, a Y-axis, and a Z-axis. The X-axis, the Y-axis, and the Z-axis are orthogonal to each other. For example, in the specification, a Z-axis direction is referred to as a first direction Z; an X-axis direction is referred to as a second direction X; and a Y-axis direction is referred to as a third direction Y. In the specification, the “thickness” of a part refers to the maximum value of the thickness in the first direction Z of the part.

The semiconductor device 1 according to the embodiment includes a semiconductor layer 10, a first electrode 20, and a second electrode 30. The semiconductor layer 10 is positioned between the first electrode 20 and the second electrode 30 in the first direction Z. The semiconductor layer 10 includes a first surface 10A, and a second surface 10B positioned at the side opposite to the first surface 10A in the first direction Z. According to the embodiment, the semiconductor layer 10 is, for example, a silicon carbide (SiC) layer.

The semiconductor device 1 includes an element region 100, and a termination region 200 surrounding the element region 100 when viewed in plan. In the specification, “when viewed in plan” means when the semiconductor device 1 is observed from the first surface 10A side. The semiconductor layer 10 includes a side surface 10C that connects the first surface 10A and the second surface 10B in the termination region 200.

The semiconductor layer 10 includes an n-type first semiconductor layer 11, a p-type second semiconductor layer 12, and an n-type third semiconductor layer 13. In the semiconductor layer 10, which is a silicon carbide layer, for example, nitrogen may be used as an n-type impurity; and boron and aluminum may be used as a p-type impurity. The second semiconductor layer 12 is located between the first semiconductor layer 11 and the first electrode 20 and contacts the first electrode 20. The third semiconductor layer 13 is located between the first semiconductor layer 11 and the second electrode 30 and contacts the second electrode 30.

The semiconductor device 1 according to the embodiment is, for example, a diode. In the diode, the first electrode 20 functions as an anode electrode; the second electrode 30 functions as a cathode electrode; the second semiconductor layer 12 functions as an anode layer; the third semiconductor layer 13 functions as a cathode layer; and the first semiconductor layer 11 functions as a drift layer.

The second semiconductor layer 12 (the anode layer) is located at the first surface 10A side in the element region 100 and forms a p-n junction with the first semiconductor layer 11. In the specification, the end of the second semiconductor layer 12 (the anode layer) at the termination region 200 side forms a boundary between the element region 100 and the termination region 200.

The first electrode 20 contacts the first surface 10A of the semiconductor layer 10. The first surface 10A of the semiconductor layer 10 includes the upper surface of the second semiconductor layer 12 and the upper surface of the first semiconductor layer 11. The first electrode 20 contacts the upper surface of the second semiconductor layer 12 in the element region 100. An end part 20A of the first electrode 20 contacts the upper surface of the first semiconductor layer 11 in the termination region 200. The end part 20A of the first electrode 20 is positioned between the end of the second semiconductor layer 12 (the anode layer) and the side surface 10C of the semiconductor layer 10 in both the second and third directions X and Y.

According to the embodiment, for example, the first electrode 20 has a stacked structure including a first film 21 and a second film 22. The first film 21 contacts the first surface 10A of the semiconductor layer 10; and the second film 22 is located on the first film 21. The first film 21 includes, for example, vanadium (V) and/or molybdenum (Mo). Vanadium forms a Schottky contact with the semiconductor layer 10. Molybdenum functions as a barrier metal. The second film 22 includes aluminum (Al). The second film 22 may further include copper (Cu). According to the embodiment, for example, the second film 22 is made of an AlCu alloy.

The third semiconductor layer 13 (the cathode layer) is positioned between the first semiconductor layer 11 and the second electrode 30 in the first direction Z. The n-type impurity concentration of the third semiconductor layer 13 is greater than the n-type impurity concentration of the first semiconductor layer 11. The second electrode 30 contacts the third semiconductor layer 13. The surface of the third semiconductor layer 13 that contacts the second electrode 30 is the second surface 10B of the semiconductor layer 10.

The semiconductor layer 10 may further include a p-type fourth semiconductor layer 14 in the termination region 200. The fourth semiconductor layer 14 functions as a guard ring layer that increases the breakdown voltage in the termination region 200. According to the embodiment, for example, multiple fourth semiconductor layers 14 continuously surround the element region 100 when viewed in plan.

The semiconductor device 1 according to the embodiment further includes a first resin member 40 and the second resin member 50.

The first resin member 40 is located on the first surface 10A in the termination region 200 and covers the end part 20A of the first electrode 20. For example, a polyimide resin can be used as the material of the first resin member 40.

The second resin member 50 covers the first surface 10A of the semiconductor layer 10, the side surface 10C of the semiconductor layer 10, the first resin member 40, and the first electrode 20. The second resin member 50 is a package that forms the outer surface of the semiconductor device 1. For example, an epoxy resin can be used as the material of the second resin member 50. A portion of the upper surface of the first electrode 20 is exposed from under the first resin member 40 and the second resin member 50 and is electrically connected with an external circuit via a connecting member such as, for example, a gold wire, etc.

The semiconductor device 1 also may include an insulating film 60 in the termination region 200. The insulating film 60 is located between the first resin member 40 and the first surface 10A of the semiconductor layer 10 in the termination region 200 and covers the first surface 10A of the semiconductor layer 10 in the termination region 200. The insulating film 60 covers the upper surface of the fourth semiconductor layer 14 (the guard ring layer). The fourth semiconductor layer 14 (the guard ring layer) is positioned directly under the insulating film 60. The insulating film 60 continuously surrounds the element region 100 when viewed in plan. The insulating film 60 increases the insulative properties of the first surface 10A in the termination region 200. For example, a silicon oxide film can be used as the insulating film 60.

The first resin member 40 covers at least an upper surface 60A of the insulating film 60. The first resin member 40 suppresses cracks and/or wire misalignment that may occur due to the thermal expansion coefficient difference between the second resin member 50 and the semiconductor layer 10. The first resin member 40 is flexible and heat-resistant, improves the adhesion with the second resin member 50, and increases the reliability of the semiconductor device 1.

The first resin member 40 includes an unevenness in the upper surface side at the side opposite to the first surface 10A in the first direction Z. According to the embodiment, the unevenness of the first resin member 40 includes multiple protrusions and multiple recesses. The multiple protrusions include, for example, a first protrusion 41A, a second protrusion 41B, a third protrusion 41C, and a fourth protrusion 41D in this order from the element region 100 side toward the side surface 10C side. The multiple recesses include, for example, a first recess 42A, a second recess 42B, and a third recess 42C in this order from the element region 100 side toward the side surface 10C side. The numbers of protrusions and recesses are not limited to the numbers shown in the drawings.

The unevenness of the first resin member 40 (the first protrusion 41A, the second protrusion 41B, the third protrusion 41C, the fourth protrusion 41D, the first recess 42A, the second recess 42B, and the third recess 42C) continuously surrounds the element region 100 when viewed in plan.

The second resin member 50 is filled into the recesses of the first resin member 40 (the first recess 42A, the second recess 42B, and the third recess 42C).

A high voltage is applied between the first electrode 20 and the second electrode 30 of the semiconductor device 1 according to the embodiment. In particular, a higher voltage can be applied during use when a silicon carbide layer is used as the semiconductor layer 10. In the semiconductor device 1 to which the high voltage is applied, a temperature rise may generate thermal stress in the second resin member 50. The end part 20A of the first electrode 20 may be deformed by being pressed due to the thermal stress of the second resin member 50. In particular, the second film 22 that includes Al deforms easily. For example, the end part 20A of the first electrode 20 may deform and penetrate between the first resin member 40 and the insulating film 60. For example, element breakdown occurs more easily if the end part 20A of the first electrode 20 deforms enough to extend to the position of the fourth semiconductor layer 14 (the guard ring layer), which is the termination breakdown voltage structure.

According to the embodiment, because the unevenness is formed in the upper surface side of the first resin member 40, the thermal stress of the second resin member 50 can be absorbed by the first resin member 40. As a result, the stress that is applied to the end part 20A of the first electrode 20 can be reduced, and the deformation of the end part 20A of the first electrode 20 can be reduced.

By forming the unevenness in the upper surface side of the first resin member 40, the contact area between the first resin member 40 and the second resin member 50 can be increased, and the adhesion between the first resin member 40 and the second resin member 50 can be improved.

Among the multiple recesses of the first resin member 40, the first recess 42A that is positioned most proximate to the element region 100 is formed at a position most proximate to the end part 20A of the first electrode 20. It is favorable for the width of the first recess 42A to be greater than the widths of the recesses (the width of the second recess 42B and the width of the third recess 42C) positioned further outward than the first recess 42A. As a result, the effect of the first recess 42A absorbing the thermal stress of the second resin member 50 can be increased, and the stress applied to the end part 20A of the first electrode 20 can be easily reduced. The width of the recess refers to the width in the second direction X and/or the width in the third direction Y.

As shown in FIG. 1, the end part 20A of the first electrode 20 includes a corner part 20A1 facing a corner 10E of the semiconductor layer 10 when viewed in plan, and a side part 20A2 extending along an outer edge 10D of the semiconductor layer 10 when viewed in plan. FIG. 2 is a cross section of the corner part 20A1 at the end part 20A of the first electrode 20; and FIG. 3 is a cross section of the side part 20A2 at the end part 20A of the first electrode 20.

There is a tendency for more stress to be applied and more deformation to occur at the corner part 20A1 than at the side part 20A2 of the end part 20A of the first electrode 20. According to the embodiment as shown in FIG. 2, the corner part 20A1 is positioned more proximate to the element region 100 than an inner side surface 60B of the insulating film 60 at the element region 100 side; and the corner part 20A1 is not positioned on the insulating film 60. The corner part 20A1 of the end part 20A of the first electrode 20 does not extend onto the upper surface 60A of the insulating film 60. By providing such a configuration, the insulating film 60 can prevent the corner part 20A1 of the end part 20A of the first electrode 20 from extending toward the termination (the side surface 10C of the semiconductor layer 10), and can reduce the deformation of the corner part 20A1.

The side part 20A2 of the end part 20A of the first electrode 20 also may be positioned more proximate to the element region 100 than the inner side surface 60B of the insulating film 60 so that the side part 20A2 does not extend onto the upper surface 60A of the insulating film 60. As a result, the insulating film 60 can prevent the side part 20A2 of the end part 20A of the first electrode 20 from extending toward the termination (the side surface 10C of the semiconductor layer 10).

According to the embodiment, the first resin member 40 covers an outer side surface 60C of the insulating film 60. The first resin member 40 continuously covers the upper surface 60A and the outer side surface 60C of the insulating film 60. As a result, the adhesion between the first resin member 40 and the insulating film 60 can be improved, and deformation of the end part 20A of the first electrode 20 in which the end part 20A penetrates between the first resin member 40 and the insulating film 60 can be reduced.

According to the embodiment, the thickness of the corner part 20A1 of the end part 20A of the first electrode 20 is less than the thickness of the side part 20A2 of the end part 20A of the first electrode 20. In other words, the volume of the corner part 20A1 of the end part 20A of the first electrode 20 is less than the volume of the side part 20A2 of the end part 20A of the first electrode 20. As a result, the deformation of the first electrode 20 can be reduced at the corner part 20A1 at which the stress tends to increase.

The volume of the side part 20A2 of the end part 20A of the first electrode 20 also may be reduced by setting the thickness of the side part 20A2 to be equal to the thickness of the corner part 20A1.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device, comprising:
an element region;
a termination region surrounding the element region;
a semiconductor layer including
a first surface, and
a second surface positioned at a side opposite to the first surface;
a first electrode contacting the first surface;
a second electrode contacting the second surface;
a first resin member located on the first surface in the termination region, the first resin member covering an end part of the first electrode; and
a second resin member covering the semiconductor layer, the first resin member, and the first electrode,
the first resin member having an unevenness formed in a surface of the first resin member at a side opposite to the first surface.

2. The device according to claim 1, wherein
the unevenness continuously surrounds the element region.

3. The device according to claim 1, wherein
the unevenness includes a plurality of recesses.

4. The device according to claim 3, wherein
the plurality of recesses include:
a first recess most proximate to the element region among the plurality of recesses; and
a second recess more distant to the element region than the first recess, and
a width of the first recess is greater than a width of the second recess.

5. The device according to claim 1, further comprising:
an insulating film located between the first surface and the first resin member in the termination region,
the end part of the first electrode including a corner part facing a corner of the semiconductor layer when viewed in plan,
the corner part being more proximate to the element region than the insulating film,
the corner part not being positioned on the insulating film.

6. The device according to claim 5, wherein
the first resin member covers an outer side surface of the insulating film.

7. The device according to claim 1, wherein
the end part of the first electrode includes:
a corner part facing a corner of the semiconductor layer when viewed in plan; and
a side part extending along an outer edge of the semiconductor layer when viewed in plan, and
a thickness of the corner part is less than a thickness of the side part.

8. The device according to claim 1, wherein
the semiconductor layer is a silicon carbide layer.

9. The device according to claim 1, wherein
the semiconductor layer includes:
a first semiconductor layer of an n-type;
a second semiconductor layer located between the first semiconductor layer and the first electrode, the second semiconductor layer contacting the first electrode and being of a p-type; and
a third semiconductor layer located between the first semiconductor layer and the second electrode, the third semiconductor layer contacting the second electrode and being of the n-type.

10. The device according to claim 1, wherein
the end part of the first electrode contacts an upper surface of the first semiconductor layer in the termination region.

11. A semiconductor device, comprising:
an element region;
a termination region surrounding the element region;
a semiconductor layer including
a first surface, and
a second surface positioned at a side opposite to the first surface;
a first electrode contacting the first surface;
a second electrode contacting the second surface;
a first resin member located on the first surface in the termination region, the first resin member covering an end part of the first electrode;
a second resin member covering the semiconductor layer, the first resin member, and the first electrode; and
an insulating film located between the first surface and the first resin member in the termination region,
the end part of the first electrode including a corner part facing a corner of the semiconductor layer when viewed in plan,
the corner part being more proximate to the element region than the insulating film,
the corner part not being positioned on the insulating film.

12. The device according to claim 11, wherein
the first resin member covers an outer side surface of the insulating film.

13. The device according to claim 11, wherein
the semiconductor layer is a silicon carbide layer.

14. The device according to claim 11, wherein
the semiconductor layer includes:
a first semiconductor layer of an n-type;
a second semiconductor layer located between the first semiconductor layer and the first electrode, the second semiconductor layer contacting the first electrode and being of a p-type; and
a third semiconductor layer located between the first semiconductor layer and the second electrode, the third semiconductor layer contacting the second electrode and being of the n-type.

15. The device according to claim 11, wherein
the end part of the first electrode contacts an upper surface of the first semiconductor layer in the termination region.

16. A semiconductor device, comprising:
an element region;
a termination region surrounding the element region;
a semiconductor layer including
a first surface, and
a second surface positioned at a side opposite to the first surface;
a first electrode contacting the first surface;
a second electrode contacting the second surface;
a first resin member located on the first surface in the termination region, the first resin member covering an end part of the first electrode; and
a second resin member covering the semiconductor layer, the first resin member, and the first electrode,
the end part of the first electrode including
a corner part facing a corner of the semiconductor layer when viewed in plan, and
a side part extending along an outer edge of the semiconductor layer when viewed in plan,
a thickness of the corner part being less than a thickness of the side part.

17. The device according to claim 16, wherein
the semiconductor layer is a silicon carbide layer.

18. The device according to claim 16, wherein
the semiconductor layer includes:
a first semiconductor layer of an n-type;
a second semiconductor layer located between the first semiconductor layer and the first electrode, the second semiconductor layer contacting the first electrode and being of a p-type; and
a third semiconductor layer located between the first semiconductor layer and the second electrode, the third semiconductor layer contacting the second electrode and being of the n-type.

19. The device according to claim 16, wherein
the end part of the first electrode contacts an upper surface of the first semiconductor layer in the termination region.

20. The device according to claim 1, wherein
the first electrode includes aluminum.
